(19) United States
(12) Patent Application Publication
(10) Pub. No.: US 2018/0102172 A1
(43) Pub. Date: Apr. 12, 2018

(54) MEMORY DEVICE AND OPERATING METHOD OF THE MEMORY DEVICE

(71) Applicant: SK hynix Inc., Gyeonggi-do (KR)

(72) Inventor: Su-Min YI, Gyeonggi-do (KR)

(21) Appl. No.: 15/603,563

(22) Filed: May 24, 2017

(30) Foreign Application Priority Data
Oct. 10, 2016 (KR) 10-2016-0130546

(51) Int. Cl. G11C 16/16; G11C 16/34; G11C 16/08; G06F 11/10; G11C 16/30

(52) U.S. Cl. CPC G11C 16/16; G11C 16/3445; G11C 16/30; G06F 11/1068; G11C 16/08

(57) ABSTRACT

A memory device includes a memory cell array including a plurality of blocks, a power supply unit suitable for generating at least one erase voltage and supplying the at least one erase voltage to the memory cell array, a control logic suitable for receiving multi-block erase information for the same plane, sequentially transmitting block address information included in the multi-block erase information to the row decoder, and outputting an erase control signal to the power supply unit when a last block address information is transmitted, and a row decoder suitable for decoding the block addresses and selecting an erase block of the memory cell array.

### CROSS-REFERENCE TO RELATED APPLICATIONS

The present application claims priority of Korean Patent. Application No. 10-2016-0130546, filed on Oct. 10, 2016, which is incorporated herein by reference in its entirety.

### BACKGROUND

### 1. Field

Exemplary embodiments of the present invention relate to a memory device and an operating method thereof, and more particularly, to a memory device capable of simultaneously erasing a plurality of blocks in the memory device and an operating method thereof.

### 2. Description of the Related Art

Recently, the paradigm of the computer environment is changed into a ubiquitous computing environment which allows users to get an access to a computer system anywhere anytime. For this reason, the use of portable electronic devices, such as mobile phones, digital cameras, laptop computers and the like, is surging. Portable electronic devices generally employ a memory system using a memory device as a data storage device. A data storage device may be used as a main memory device or an auxiliary memory device of a portable electronic device.

A data storage device using a memory device has excellent stability and durability because the data storage device does not include a mechanical driving unit. Also, the data storage device using a memory device is advantageous in that it may access data quickly and consume a small amount of power. Non-limiting examples of a data storage device having these advantages include a Universal Serial Bus (USB) memory device, a memory card with diverse interfaces, a Solid-State Drive (SSD) and so forth.

A non-volatile memory device may be divided into a plurality of memory regions. A program operation or erase operation may be performed in a unit of a memory region. For example, a non-volatile memory device may perform a read and a program operation in a unit of a page and may perform an erase operation in a unit of a block. A memory device cannot be overwritten. That is, in a memory device, data can be programmed into only an erased region (e.g., page). In order to write data in a region that is not empty, a program operation needs to be performed after the data of a corresponding region is erased.

The time taken to erase data in a memory device is relatively slower than the time taken to program and read data. For example, the time taken to erase data may be 10 times greater than the time taken to program data. While data is erased in a memory device, an operation for programming and reading data may be performed. When erasing data, the memory device may perform the erase operation in a unit of a block.

### SUMMARY

Various embodiments of the present invention are directed to a device and method, which are capable of selecting a multi-block and erasing the data of the selected blocks at a time when a memory device performs an erase operation.

Various embodiments of the present invention propose a device and method, which are capable of selecting several blocks located in the same plane, that is, an object of erasure, when a command for simultaneously erasing several blocks is inputted to the same plane, performing an operation for simultaneously erasing the several blocks, and performing an erase verification operation for each block.

In an embodiment a memory device includes a memory cell array including a plurality of blocks. Each of the blocks may include a block selection unit and a block cell array, a power supply unit suitable for generating at least one erase voltage and supplying the at least one erase voltage to the memory cell array, a control logic suitable for receiving multi-block erase information for the same plane, sequentially transmitting block address information included in the multi-block erase information to the row decoder and outputting an erase control signal to he power supply unit when a last block address information is transmitted. The memory device can simultaneously erase a plurality of blocks selected in the same plane of the memory cell array.

In an embodiment, an operating method of a memory device may include receiving multi-block erase information for an identical plane of a memory cell array including a plurality of blocks, decoding block address information included in the multi-block erase information for the identical plane of the memory cell array, supplying an erase voltage to blocks of the identical plane of the memory cell array based on the decoded block address information, and simultaneously erasing a plurality of blocks selected in the identical plane of the memory cell array using the erase voltage.

### BRIEF DESCRIPTION OF THE DRAWINGS

The above and other features and advantages of the present invention will become more apparent to those skilled in the art to which the present invention pertains by the following detailed description with reference to the attached drawings in which;

FIG. 1 is a block diagram illustrating an example of a data processing system including a memory system in accordance with an embodiment of the present invention.

FIG. 2 illustrates an example of a memory device in a memory system in accordance with an embodiment of the present invention.

FIG. 3 is a schematic diagram illustrating a memory cell array circuit of a memory block in a memory device in accordance with an embodiment of the present invention.

FIG. 4 illustrates a three-dimensional structure of a memory device in a memory system in accordance with an embodiment of the present invention.

FIG. 5 is a diagram illustrating an example of multi-block erase information inputted to the memory device according to various embodiments of the present invention.

FIG. 6 is a diagram illustrating a configuration of the memory device according to various embodiments of the present invention.

FIG. 7 is a diagram illustrating an example of a block configuration in the memory device according to various embodiments of the present invention.

FIG. 8 is a diagram illustrating an example of the operation of a block selection unit and a block in the memory device according to various embodiments of the present invention.

FIG. 9 is a flowchart illustrating an erase operation of the memory device according to various embodiments of the present invention.

FIGS. 10 to 15 are block diagrams illustrating examples of a data processing system including a memory system according to an embodiment of the present invention.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

It is noted that the drawings are simplified schematics and as such are not necessarily drawn to scale,. In some instances, various parts of the drawings may have been exaggerated in order to more dearly illustrate certain features of the illustrated embodiments.

It is further noted that in the following description, specific details are set forth for facilitating the understanding of the present invention, however, the present invention may be practiced without some of these specific details. Also, it is noted, that well-known structures and/or processes may have only been described briefly or not described at all to avoid obscuring the present disclosure with unnecessary well known details.

It is also noted, that in some instances, as would be apparent to those skilled in the relevant art, an element (also referred to as a feature) described in connection with one embodiment may be used singly or in combination with other elements of another embodiment, unless specifically indicated otherwise.

Hereinafter, the various embodiments of the present invention will be described in detail with reference to the attached drawings.

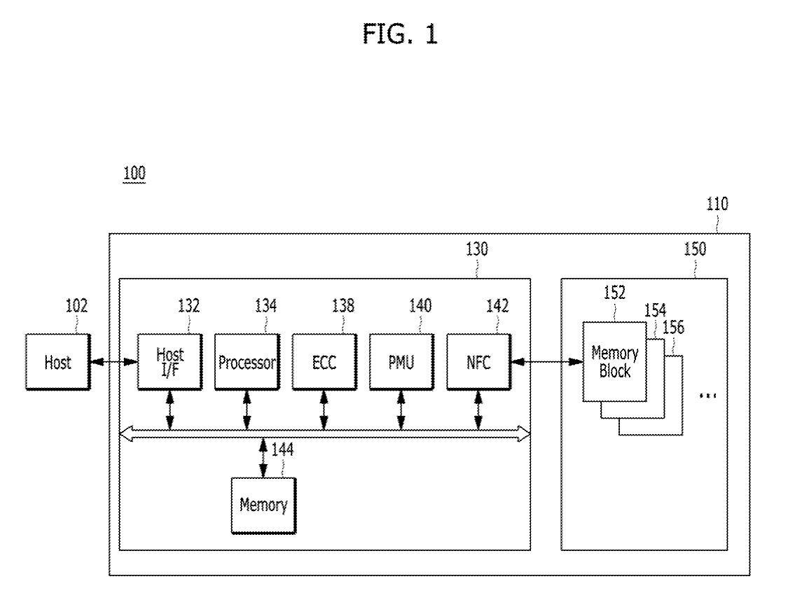

FIG. 1 illustrates a data processing system 100 including a memory system 110, according to an embodiment of the present invention.

Referring to FIG. 1, the data processing system 100 may include a host 102 operatively coupled to the memory system 110,

The host 102 may be any suitable electronic device. The host 102 may be or include, for example a portable electronic device such as a mobile phone, an MP3 player and a laptop computer or a non-portable electronic device such as a desktop computer, a game player, a television (TV) and a projector,

The memory system 110 may operate in response to a request from the host 102. For example, the memory system 110 may store data provided by the host 102 and the memory system 110 may also provide stored data to the host 102. Data which are stored in the memory system may be accessed by the host 102. The memory system 110 may be used as a main memory or an auxiliary memory of the host 102. The memory system 110 may be implemented with any one of various storage devices, according to the protocol of a host interface to be coupled electrically with the host 102. The memory system 110 may be implemented with any one of various storage devices, such as a solid state drive (SSD), a multimedia card (MMC), an embedded MMC (eMMC), a reduced size MMC (RS-MMC) a micro-MMC, a secure digital (SD) card, a mini-SD, a micro-SD, a universal serial bus (USB) storage device, a universal flash storage (UFS) device, a compact flash (CF) card, a smart media (SM) card, a memory stick, and the like.

The storage devices forming the memory system 110 may be implemented with a volatile memory device, such as, a dynamic random access memory (DRAM) and a static random access memory (SRAM) or a nonvolatile memory device such as a read only memory (ROM), a mask ROM (MROM), a programmable ROM (PROM), an erasable programmable ROM (EPROM), an electrically erasable programmable ROM (EEPROM), a ferroelectric random access memory (FRAM), a phase-change RAM (PRAM), a magnetoresistive RAM (MRAM), a resistive RAM (RRAM) and a flash memory.

The memory system 110 may include a memory device 150 and a controller 130. The memory device 150 may store data which may be accessed by the host 102. The controller 130 may control data exchange between the memory device 150 and the host 102. For example, under the control of the controller 130, data received from the host may be stored in the memory device 150, and stored data in the memory device 150 may be read and transmitted to the host 102.

The controller 130 and the memory device 150 may be integrated into one semiconductor device, For instance, the controller 130 and the memory device 150 may be integrated into one semiconductor device to form a solid state drive (SSD). When the memory system 110 is used as an. SSD, the operation speed of the host 102 that is electrically coupled with the memory system 110 may be significantly increased.

The controller 130 and the memory device 150 may be integrated into one semiconductor device to form a memory card, such as, for example, a Personal Computer Memory Card International Association (PCMCIA) card, a compact flash (CF) card, a smart media card (SMC), a memory stick, a multimedia card (MMC) an RS-MMC, a micro-MMC, a secure digital (SD) card, a mini-SD, a micro-SD, an SDHC, and a universal flash storage (UFS) device.

The memory device 150 may retain stored data even when power is blocked, store the data provided from the host 102 during a write operation, and provide stored data to the host 102 during a read operation. The memory device 150 may include a plurality of memory blocks 152 154 and 156. Each of the memory blocks 152, 154 and 156 may include a plurality of pages. Each of the pages may include a plurality of memory cells which are electrically coupled to a word line (WL). The memory cells may be single bit cells or multi-bit cells. The memory cells may be arranged in a two or three dimensional stacked structure. The memory device 150 may be a nonvolatile memory device, for example a flash memory. The flash memory may have a three-dimensional (3D) stack structure,

The controller 130 may include a host interface (I/F) unit 132, a processor 134, an error correction code (ECC) unit 138, a power management unit (PMU) 140, a NAND flash controller (NFC) 142, and a memory 144.

The host interface unit 132 may process commands and data provided from the host 102, and may communicate with the host 102 through at least one of various interface protocols such as universal serial bus (USB), multimedia card (MMC), peripheral component interconnect express (PCI-e), serial attached SCSI (SAS), serial advanced technology attachment (SATA), parallel advanced technology attachment (PATA), small computer system interface (SCSI), enhanced small disk interface (ESDI), and integrated drive electronics (IDE).

The ECC unit 138 may detect and correct errors in the data read from the memory device 150 during the read operation. The ECC unit 188 may not correct error bits when the number of the error bits is greater than a threshold number of correctable error bits, and may output an error correction fail signal indicating failure in correcting the error bits.

The ECC unit 138 may perform an error correction operation based on any suitable method including a coded modulation such as a low density parity check (LDPC) code, a Bose-Chaudhuri-Hocquenghem (BCH) code, a turbo code, a Reed-Solomon (RS) code, a convolution code, a recursive systematic code (RSC), a trellis-coded modulation (TCM), a Block coded modulation (BCM), and so on. The ECC unit 138 may include all circuits, systems or devices for the error correction operation.

The PMU 140 may provide and manage power for the controller 130, that is, power for the component elements included in the controller 130.

The NFC 142 may serve as a memory interface between the controller 130 and the memory device 150 to allow the controller 130 to control the memory device 150 in response to a request from the host 102. The NFC 142 may generate control signals for the memory device 150 and process data under the control of the processor 134 when the memory device 150 is a flash memory and, in particular, when the memory device 150 is a NAND flash memory. It is noted that a different memory interface may be employed depending upon the type of memory device employed.

The memory 144 may serve as a working; memory of the memory system 110 and the controller 130. The memory 144 may store data for driving the memory system 110 and the controller 130. The controller 130 may control the memory device 150 in response to a request from the host 102. For example, the controller 130 may provide data read from the memory device 150 to the host 102 and store the data provided from the host 102 in the memory device 150. When the controller 130 controls an operation of the memory device 150 such as, for example, a read, write, program and erase operation, the memory 144 may store data used by the controller 130 and the memory device 150 for the operation.

The memory 144 may be implemented with a volatile memory such as, for example, a static random access memory (SRAM) or a dynamic random access memory (DRAM). As described above, the memory 144 may store data used by the host 102 and the memory device 150 for an operation including a read and a write operation. For such storing the data, the memory 144 may include a program memory, a data memory, a write buffer, a read buffer, a map buffer, and the like.

The processor 134 may control the general operations of the memory system 110, and a write operation or a read operation for the memory device 150 in response to a write request or a read request received from the host 102, respectively. For example, the processor 134 may drive firmware, which is referred to as a flash translation layer (FTL), to control the general operations of the memory system 110. The processor 134 may be implemented, for example, with a microprocessor or a central processing unit (CPU).

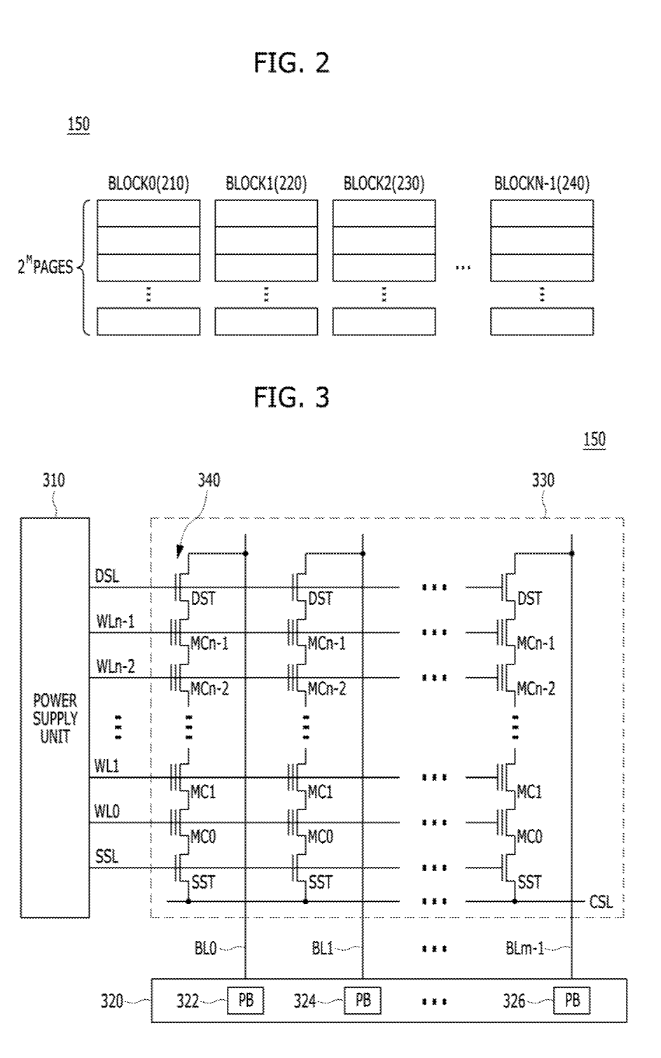

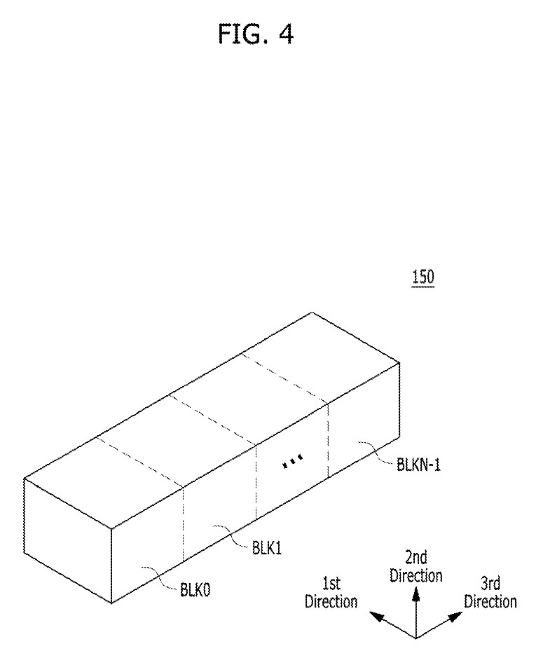

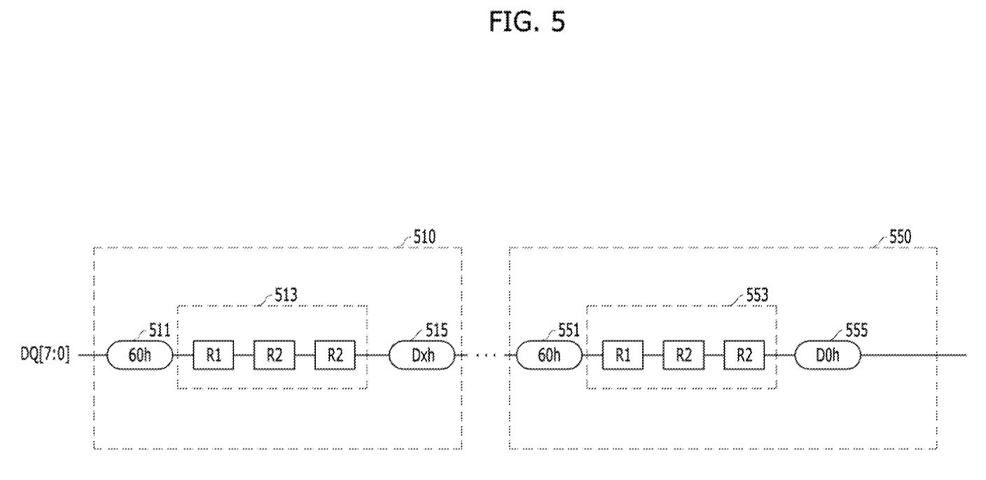

FIG. 2 illustrates an example of a memory device in a memory system in accordance with an embodiment of the present invention. FIG. 3 is a schematic diagram illustrating a memory cell array circuit of memory blocks in a memory device in accordance with an embodiment of the present invention. FIG. 4 illustrates a three-dimensional structure of a memory device in a memory system in accordance with an embodiment of the present invention, and shows that the memory device may be realized as a 3-dimensional non-volatile memory device.

Referring to FIG. 2, the memory device 150 may include a plurality of memory blocks. For example, the memory device 150 may include a zeroth memory block (BLOCK0) 210, a first memory block (BLOCK1) 220, a second memory block (BLOCK2) 230 and an N-1^{th} memory block (BLOCKN-1) 240. Each of the memory blocks 210 to 240 may include a plurality of pages, for example, 2^{M} number of pages (2^{M} PAGES). Each of the pages may include a plurality of memory cells which are electrically coupled to a word line.

Also, the memory device 150 may include a plurality of memory blocks, as single level cell (SLC) memory blocks and/or multi-level cell (MLC) memory blocks, according to the number of bits which may be stored or expressed in each memory cell. The SLC memory block may include a plurality of pages which are implemented with memory cells each capable of storing 1-bit data. The MLC memory block may include a plurality of pages which are implemented with memory cells each capable of storing multi-bit data, for example, two or more-bit data. An MLC memory block including a plurality of pages which are implemented with memory cells that are each capable of storing 3-bit data may also be referred to as a triple level cell (TLC) memory block.

Each of the memory blocks 210 to 240 may store the data provided from the host 102 during a write operation, and provide the stored data to the host 102 during a read operation.

Referring to FIG. 3, the memory block 330 may include a plurality of cell strings 340 which are electrically coupled to a plurality of corresponding bit lines BL0 to BLm-1, respectively. The cell string 340 of each column may include at least one drain select transistor DST and at least source select transistor SST. A plurality of memory cell transistors MC0 to MCn-1 may be electrically coupled in series between the select transistors SST and DST. The respective memory cells MC0 to MCn-1 may be configured by multi-level cells (MLC) each of which stores data information of a plurality of bits. For reference, in FIG. 3, ‘DSI’ denotes a drain select line (i.e., a string select line), ‘SSL’ denotes a source select line (i.e., a ground select line) and ‘CSC’ denotes a common source line.

A read/write circuit 320 of the memory device 300 may be controlled by the control circuit and may serve as a sense amplifier or a write driver according to an operation mode. During a verification/normal read operation the read/write circuit 320 may serve as a sense amplifier for reading data from the memory cell array. Also, during a program operation, the read/write circuit 320 may serve as a write driver which drives bit lines according to data to be stored in the memory cell array. The read/write circuit 320 may receive data to be written in the memory cell array from a buffer (not shown), during the program operation, and may drive the bit lines according to the inputted data. To this end, the read/write circuit 320 may include a plurality of page buffers (PBs) 322, 324 and 326 respectively corresponding to columns (or bit lines) or pairs of columns (or pairs of bit lines), and a plurality of latches (not shown) may be included in each of the page buffers 322, 324 and 326.

The memory device 150 may be realized as a 2-dimensional or 3-dimensional memory device. For example, as shown in FIG. 4, in the case where the memory device 150 is realized as a 3-dimensional nonvolatile memory device, the memory device 150 may include a plurality of memory blocks BLK0 to BLKN-1. For example, the respective memory blocks BLK0 to BLKN-1 may be realized as a 3-dimensional structure by including a structure which extends in first to third directions (for example, the x-axis direction, the y-axis direction and the z-axis direction).

The respective memory blocks BLK0 to BLKN-1 may include a plurality of NAND strings extending in the second direction. The plurality of NAND strings may be provided in the first direction and the third direction. Each NAND string may be electrically coupled to a bit line, at least one string select line, at least one source select line, a plurality of word lines, at least one dummy word line, and a common source line, and include a plurality of transistor structures.

As described above, a non-volatile memory device (e.g., a flash memory device) may include a plurality of memory regions. For example, as shown in FIG. 2, each of memory regions may have the structure of page and blocks. One block may include a plurality of pages. For example, 1 page may have a size of 4 Kbytes, and 1 block may have a size of 512 Kbytes. A memory device may process read and write operations in a unit of a page and may perform an erase operation in a single block or simultaneously in a plurality of blocks in the memory device. When performing a write operation, the memory device may write data in an empty page only. That is, in order to write data in a page that is not empty, the memory device may first erase the data of the corresponding page and then write data in the corresponding page. A memory device may have a fast read and write speed, but may have a relatively slow erase speed. For example, a read speed for a page may be 20 μsec, a write speed for a page may be 200 μsec, and an erase speed of a single block may be msec. Accordingly, in order to improve the access speed of a memory device, an erase speed may be enhanced.

Various embodiments of the present invention provide a device and method capable of erasing several blocks within the same plane at a time. The memory device provides a multi-block erase scheme for erasing a plurality of blocks when performing a single erase operation in order to enhance the erase speed. For example, the memory device may select at least two blocks from the same plane and erase the selected blocks at a time. In accordance with such a multi-block erase operation, an erase time per unit bit can be reduced because more memory regions can be erased within a unit time for an erase operation.

The memory device may receive the addresses of a multi-block to be erased from a control unit. Information received from the control unit may be multi-block erase information for the same plane. In accordance with one embodiment, the control unit may be the control unit of an electronic device. In accordance with one embodiment, the control unit may be a solid state drive (SSD) coupled to a host device, such as that shown in FIG. 1. In the case of the SSD, a host device may be an electronic device. In the following description, an SSD is described as an example,

The memory device (e.g., 150 of FIG. 1) may receive multi-block erase information for the same plane, transmitted by a host (e.g., the host 102 of FIG. 1), through a controller (e.g., 130 of FIG. 1). The memory device may newly designate a command set for erasing a plurality of blocks within the same plane based on received multi-block erase information for the same plane, and may select blocks to be erased within the same plane based in the designated command set. When an erase command for erasing several blocks at the same time is inputted to the same plane, the memory device may apply an erase voltage to several blocks located in one plane, that is, an object of erasure, at a time. After performing the erase operation, the memory device may perform an erase verification operation for each block. The memory device may determine whether it will apply a next erase voltage based on a result of the verification, and may apply an erase voltage to only a block that requires an additional erase voltage (i.e., an erase block for which the multi-block erase operation has failed). The memory device may terminate an erase operation after erase verification is performed (i.e., a pass) for all of the target blocks of the multi-block erase operation.

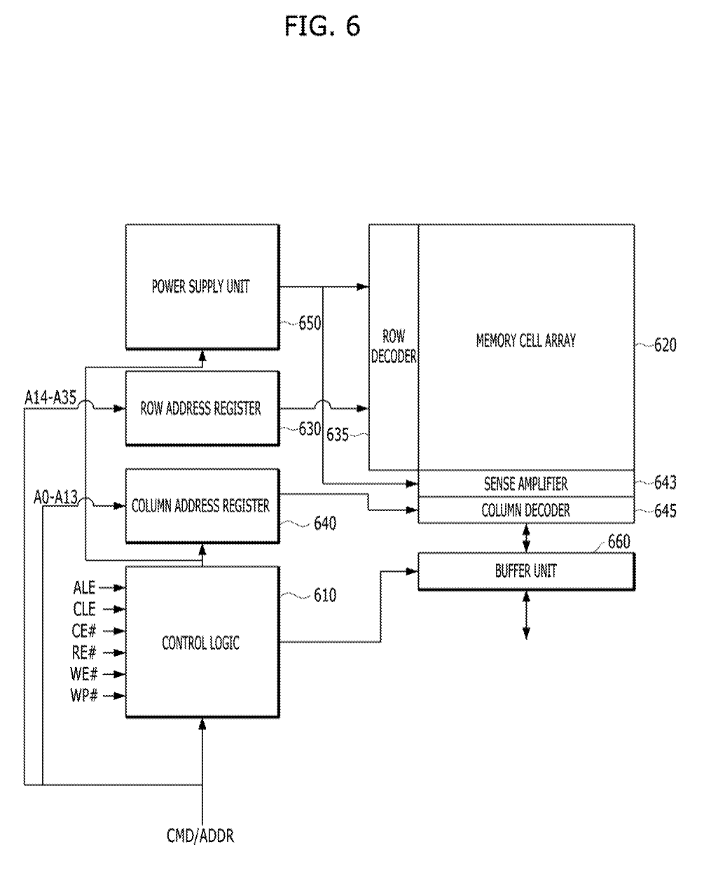

FIG. 5 is a diagram illustrating an example of a multi-block erase information performed on the memory device according to various embodiments of the present invention.

Referring to FIG. 5, multi-block erase information may be transmitted to the memory device by the control unit of an electronic device or the controller (e.g., 130 of FIG. 1) of a memory system (e.g., an SSD). A multi-block erase command may include information about a plurality of blocks to be erased in one plane (or the same plane). The information about a plurality of blocks to be erased may include at least one piece of preceding block erase information 510 and the last block erase information 550. The at least one piece of preceding block erase information 510 may include a first erase command (i.e., Block Erase Setup Command1) 511, address information 513 (e.g., R1, R2, R2) regarding a block to be erased and a second erase command 515 (i.e., Block Erase Setup Command2). In this case, the first erase command 511 (e.g., 60h) may indicate the start of an erase block. The second erase command 515 (e.g., Dxh) may indicate the end of address information for a block to be erased and may be information indicating that another piece of block erase information for the same plane is subsequent.

The last block erase information 550 of the multi-block erase information may include a first erase command 551, address information 553 for the last block and an erase confirm command 555, The erase confirm command 555 of the last block erase information 550 may be a command indicative of the end of the address of the last block and the end of the multi-block erase information. For example, the erase confirm command 555 (e.g., Dxh) may be indicative of the last erase block of the multi-block erase information. When recognizing the erase confirm command 555, the memory device may erase multiple selected blocks at a time by supplying an erase voltage to a multi-block to be selected.

When multi-block erase information having a structure, such as that of FIG. 5 is received, the memory device may analyze block addresses included in the received erase information, may select: corresponding blocks based on a result of the analysis, and may erase the data of the selected blocks at a time (or at the same time) when the erase confirm command 555 is recognized.

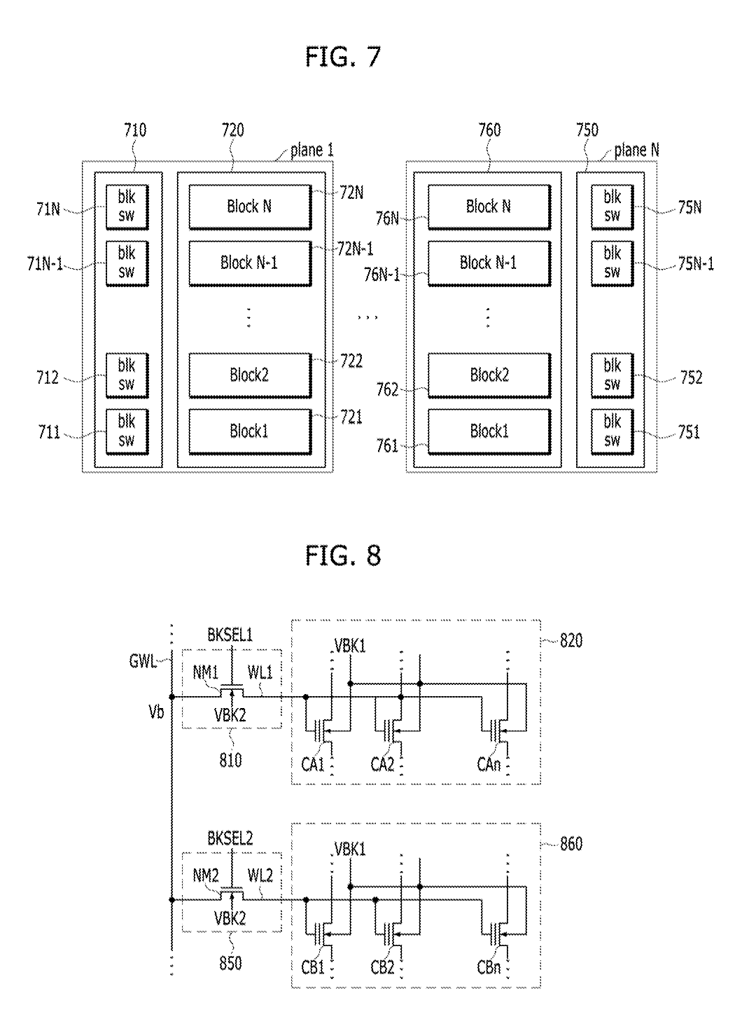

FIG. 6 is a diagram illustrating a configuration of a memory device according to various embodiments of the present invention.

Referring to FIG. 6, the memory device (e.g., memory device 150 of FIG. 1) may include a control logic (or command interface logic) 610, a memory cell array (e.g., a NAND flash array) 620, a row address register (or an X decoder address register) 630, a row decoder (or an X decoder) 635, a column address register (or a Y decoder address register) 640, a sense amplifier 643, a column decoder (or a Y decoder) 645, a power supply unit (or a program erase controller) 650 and a buffer unit (or input/output buffers and latches) 660.

In the memory device, the control logic 610 may receive a command signal CMD and/or an address signal ADD in response to external control signals ALE, CLE, CE#, RE#, WE# and WP#. The control logic 610 may control the execution of one of operations corresponding to a read command READ, a program command PGM and an erase command ERS in response to the command signal CMD. The control logic 610 may generate an X (or row) address signal and/or a Y (or column) address signal based on the address signal ADDR.

The power supply unit 650 may include a bulk voltage generator and at least one bias voltage generator. The bulk voltage generator may generate a bulk voltage in response to one of the read command READ, the program command PGM and the erase command ERS of the control logic 610, and may supply the bulk voltage to the P well of the memory cell array 620. For example, the bulk voltage generator may generate a bulk voltage with a low voltage level (e.g., 0 V) in response to the read command READ or the program command PGM. For another example, the bulk voltage generator may generate a bulk voltage with a high voltage level (hereinafter referred to as an “erase voltage”, for example, 20 V) in response to the erase command ERS. After an erase operation, if there is a cell on which the erase operation has not been normally performed based on data output by the column decoder 645, the bulk voltage generator may control the level of a bulk voltage (i.e., erase voltage). By way of example, if an erase operation has not been normally performed, the bulk voltage generator may update the level of an erase voltage (e.g., increase the level at intervals of 0.5 V or 1 V) and output the updated erase voltage.

The row address register 630 may temporarily store the X (or row) address information under the control of the control logic 610. For example, when multi-block erase information, such as that of FIG. 5, is received, the row address register 630 may buffer X addresses (e.g., A14-A35) until an erase block is selected (e.g., until the row decoder 635 decodes a block address and selects a corresponding block of the memory cell array 620). The row decoder 635 is coupled to the memory cell array 620 through word lines WL, and may select at least one of the word lines in response to an X (or row) address. In accordance with one embodiment, in erase mode, the row decoder 635 may decode an X address of the row address register 630 and apply a decoding signal for selecting a block of the memory cell array 620.

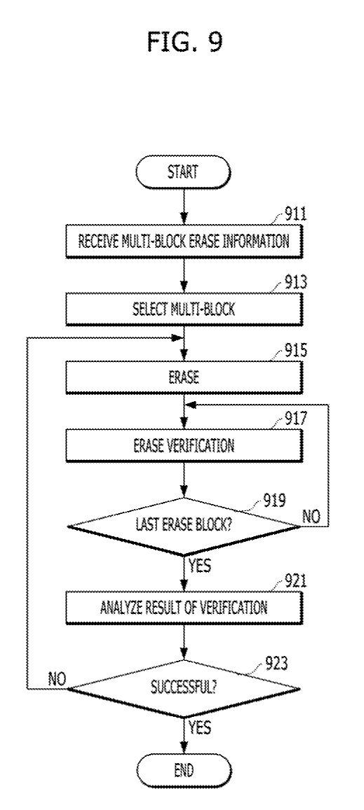

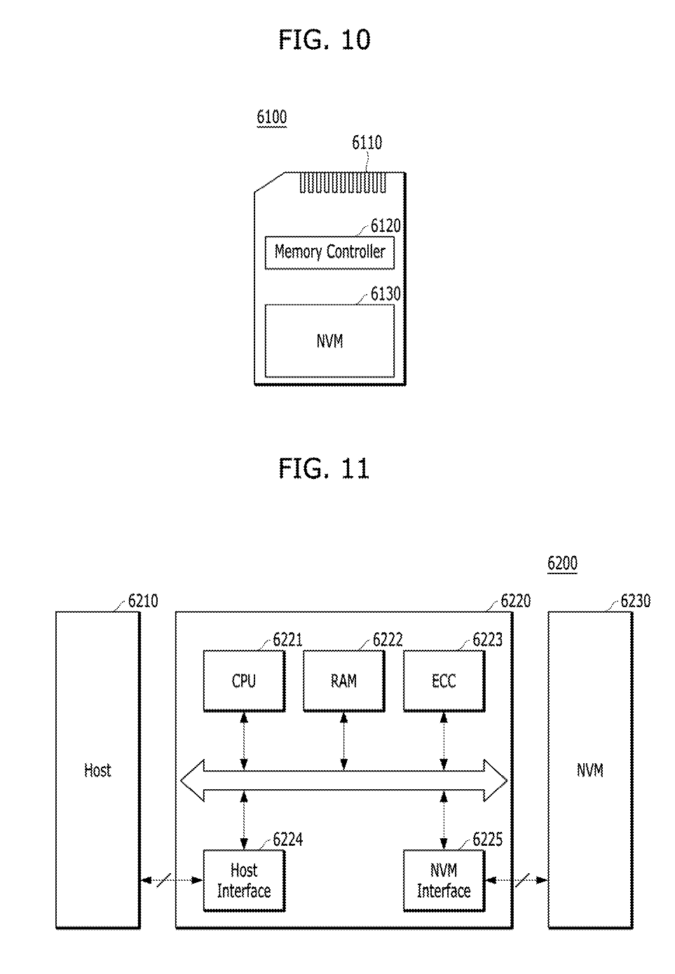

The memory cell array 620 may include a block selection unit (e.g., 711-71N and 751-75N of FIG. 7, 810 and 820 of FIG. 8) and a plurality of memory regions. In this case, a memory region may be a block and/or a page, and may have a structure, such as that shown in FIG. 2. The block selection unit of the memory cell array 620 may select a corresponding block of memory cell blocks in response to the decoding signal of the row decoder 635. For example, the block selection unit may couple the local word lines of a selected block (or memory cell blocks) to respective global word lines. Furthermore, the block selection unit may couple the drain selection line of a selected memory cell block to a global drain selection line and couple the source selection lines of a selected memory cell block to a global source selection line.

The column address register 640 may temporarily store Y (or column) address information under, the control of the control logic 610. For example, when erase verification is performed after a multi-block is erased the column address register 640 may buffer Y (or column) addresses (e.g., A0-A13) until an erase verification block is selected (e.g., until the column decoder 645 decodes the erase verification block). The sense amplifier 643 may sense and amplify the weak signal of the memory cell array 620. The column decoder 645 is coupled to the memory cell array 620 through bit lines, and may select at least one of the bit lines in response to output of the column address register 640. In one embodiment, the column decoder 645 may select a block for selecting a result (i.e., pass or fail) of verification for an erased block in erase verification mode.

The buffer unit 660 may receive data for programming (or writing) external data DATA into the memory cell array 620 under the control of the control logic 610. Also, the buffer unit 660 may sense data programmed into the memory cell array 620 and output the sensed data to the outside (e.g., the controller 130 of FIG. 1). Furthermore, the buffer unit 660 may provide a result of the program or read to the control logic 610. For example, the buffer unit 660 as a verification circuit may perform a verification operation in order to detect a result of an operation and provide a result of the verification, for example, a pass or fail (P/F) signal to the control logic 610.

The memory device having such a configuration may simultaneously erase a multi-block according to the following operation.

When multi-block erase information, such as that shown in FIG. 5, is received, the control logic 610 may check the first erase command 511 and the second erase command 515 and may control the address information 513 included in corresponding block erase information so that it is applied to the row address register 630. In response to the row address information 513 applied thereto, the row decoder 635 may decode an X address of the row address register 630 and generate a block selection signal for a block to be erased. Accordingly, a corresponding block selection unit of the memory cell array 620 becomes on, and the corresponding block may be selected as an erase block. If the second erase command 515 subsequent to address information is not an erase confirm command, the control logic 610 may recognize that another subsequent erase block is present, and may perform control so that a next block to be erased is selected by repeating the above operation. The control logic 610 performs control so that address information included in erase information for a preceding block is applied to the row address register 630 until erase information for the last block is received. The row decoder 635 may decode pieces of address information stored in the row address register 630 and select corresponding blocks of the memory cell array 620. That is, the control logic 610 may perform control so that corresponding blocks of the memory cell array 620 are selected based on multi-block erase information,

When the erase confirm command 555 is checked in multi-block erase information, such as that shown in FIG. 5, the control logic 610 may recognize that the erase confirm command 555 is the last block erase information for a multi-block to be erased. The row decoder 635 may decode the address of the last erase block in the row address register 630 and select a corresponding erase block. When the last block erase information is checked in the multi-block erase information, the control logic 610 may control the power supply unit 650 so that an erase voltage is supplied to the memory cell array 620. In response thereto, the memory cell array 620 may erase the data of selected blocks at the same time (i.e., at a time) in response to the supplied erase voltage.

FIG. 7 is a diagram illustrating an example of a block configuration in the memory device according to various embodiments of the present invention.

Referring to FIG. 7, the blocks may be arranged in a plurality of planes 1-a plane N. Each of the planes may include a plurality of blocks 721-72N, . . . , 761-76N. Each of the blocks may include a plurality of pages. The blocks 721-72N and 761-76N may include respective block selection units (or block switches) 711-71N and 751-75N. The block selection units 711-71N and 751-75N may be selected by the decoding signal of the X decoder 635 of FIG. 6. For example, in erase mode, i.e., when a multi-block erase command is received by the memory device, the block selection units 710 and 750 may become on or off in response to the output of the X decoder 635 and select a corresponding block as an erase block or non-erase block.

FIG. 8 is a diagram illustrating an example of the operation of a block selection unit and a block in the memory device according to various embodiments of the present invention.

Referring to FIG. 8 a first block may include a block selection unit 810 and a memory cell block 820, and a second block may include a block selection unit 850 and a memory cell block 860. In the following description, for example, the first block may be described as being selected as an erase block, and the second block may be described as being not selected as an erase block (Le., a non-erase block). When an erase operation is performed, block selection signals BKSEL1 and BKSEL2 may become signals decoded by the X decoder 635 of FIG. 6. The block selection signal BKSEL1 may become a signal for selecting (i.e., ON) the first block as an erase block, and the block selection signal BKSEL2 may become a signal for selecting (i.e., OFF) the second block as a non-erase block.

When an erase operation is performed, a bias voltage Vb of 0 V may be applied to a global word line GWL and an erase voltage (e.g., a bulk voltage of 20 V) VBK1 supplied by the program erase controller 650 of FIG. 6 may be applied to the P wells of memory cells CA1-CAn and CB1-CBn (where n is an integer). The sources and drains of the memory cells CA1-CAn and CB1-CBn may become a floating state. Furthermore, the block selection signal BKSEL1 of a voltage (Vcc) level may be applied to the gate of an NMOS transistor NM1 coupled between the global word line GWL and the local word line WL1 of the selected memory cell block 820 (i.e., to be erased). A bulk voltage VBK2 of 0 V is applied to the substrate (not shown) of the NMOS transistor NM1. The NMOS transistor NM1 is turned on in response to the block selection signal BKSEL1, and thus the local word line WL1 may be coupled to the global word line GWL. As a result, the voltage of the local word line WL1 becomes 0 V, and thus a voltage difference of 20 V may be generated between the control gates (not shown) of the memory cells CA1-CAn coupled to the local word line WL1 and the P wells of the memory cells CA1-CAn, respectively. Accordingly, electrons of the floating gates of the memory cells CA1-CAn are discharged to the P wells so an erase operation may be performed on the memory cell block 820.

The block selection signal BKSEL2 of 0 V may be inputted to the gate of an NMOS transistor NM2 coupled between the global word line GWL and the local word line WL2 of the memory cell block 860 that has not been selected (i.e., to be not erased). Furthermore, the bulk voltage VBK2 of 0 V is applied to the substrate of the NMOS transistor NM2. The NMOS transistor NM2 is turned off in response to the block selection signal BKSEL2, and thus the local word line WL2 may be separated from the global word line GWL. As a result, the local word line WL2 may become a floating state. Thereafter, the bulk voltage VBK1 of 20 V applied to the P wells of the memory cells CB1-CBn is induced to the local word line WL2 due to a capacitive coupling phenomenon, and thus a voltage level of the local word line WL2 may be boosted up to about 19 V. Accordingly, a voltage difference of about 1 V is generated between the local word line WL2 and the P wells of the memory cells CB1-CBn, so electrons may not be discharged from the floating gates of the memory cells CB1-CBn. As a result, while the erase operation is performed on the memory cell block 820, an erase operation may not be performed on the memory cell block 860.

An erase method of the memory device according to various embodiments of the present invention may include receiving a plurality of pieces of block erase information based on multi-block erase information, consecutively selecting blocks based on the plurality of pieces of block erase information, respectively, and electrically coupling the local word lines of the selected blocks and global word lines. Thereafter, when the last block erase information included in multi-block erase information is checked, the memory device may perform an operation for erasing the data of the selected blocks at the same time by applying an erase voltage of a positive potential to the global word line and applying a bulk voltage higher than the erase voltage to the bulk of corresponding memory cells in response to a batch erase command.

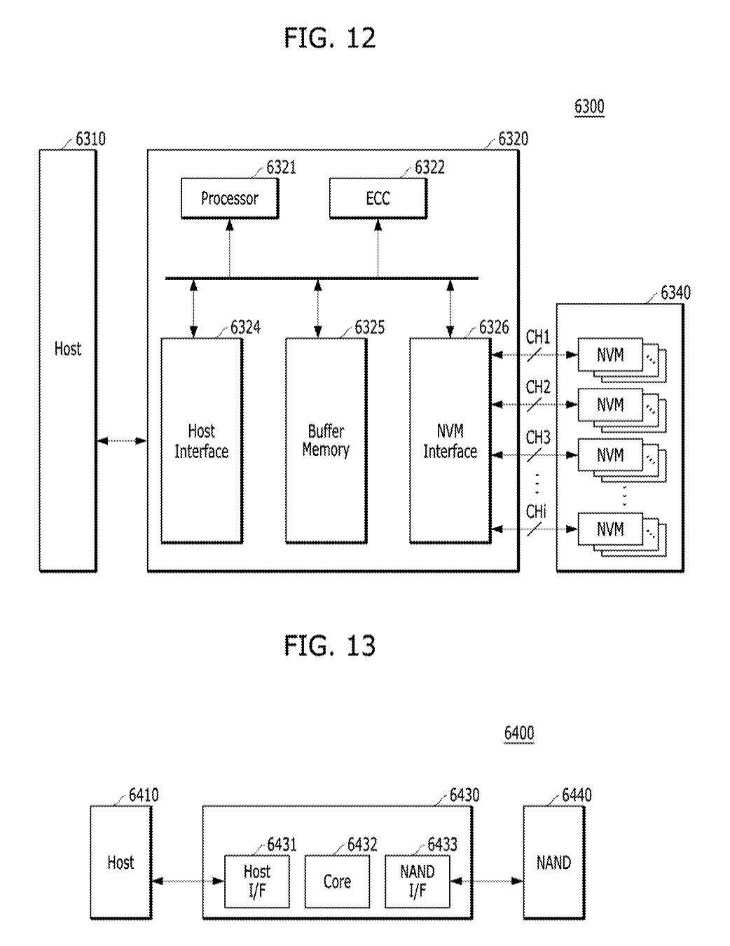

FIG. 9 is a flowchart illustrating an erase operation of the memory device according to various embodiments of the present invention.

Referring to FIG. 9, the memory device may receive multi-block erase information at step 911. The memory device may be coupled to an electronic device or a memory system (e.g., SSD). The control unit of the electronic device or the controller of the memory system may generate the multi-block erase information and send it to the memory device. The multi-block erase information may have a structure, such as that shown in FIG. 5. As shown in FIG. 7, pieces of erase information for respective blocks may be erase information for blocks located in the same plane. Furthermore, the erase information for each of the blocks may have address information for a block consecutive to a previous block and may have address information for a block not consecutive to a previous block.

When the multi-block erase information is received, the memory device may sequentially decode pieces of address information included in the multi-block erase information and select corresponding blocks of the memory cell array 620 at step 913. The multi-block erase Information may include at least one piece of preceding block erase information, such as 510 of FIG. 5, and pieces of the last block erase information, such as 550 of FIG. 5. The memory device may select an erase block based on the preceding block erase information 510 by turning on a corresponding block selection unit within the memory cell array 620, and may recognize that another erase block consecutive to the second erase command 515 is present. Furthermore, the memory device may select the last erase block based on the last block erase information 550 by turning on a corresponding block selection unit within the memory cell array 620. When the erase confirm command 555 is checked (i.e., when a block corresponding to the address of the last block is selected) in the multi-block erase information, such as that shown in FIG. 5, the memory device may recognize that the selection of a multi-block has been completed. At step 915, the memory device may control the power supply unit 650 so that an erase voltage is applied to the memory cell array 620. Accordingly, the erase voltage may be applied to the selected blocks of the memory cell array 620, and thus the data of the selected blocks may be erased at the same time. That is, an erase operation can be performed on a multi-block of the memory cell array 620 by the supply of a single erase voltage.

For example, if four pieces of erase block information are included in the multi-block erase information, each of the pieces of erase information of the first to the third blocks may have a structure, such as the preceding block erase information 510, and the erase information of the fourth block may have a structure, such as the last block erase information 550. The memory device may sequentially analyze the pieces of erase information of the first to the third blocks, may decode corresponding block addresses, and may sequentially turn on corresponding block selection units in the memory cell array 620. Thereafter, when analyzing the erase information of the fourth block the memory device may recognize that the erase information of the fourth block is the last block erase information of the multi-block erase information based on the erase confirm command 555, may decode the address of the last block, and may turn on a corresponding block selection unit of the memory cell array 620. In such a case, in the memory cell array 620, the four blocks may have been selected as erase blocks in the same plane based on the multi-block erase information, and the remaining blocks may have been selected as non-erase blocks. After selecting the last erase block, the memory device may control the power supply unit 650 so that it generates an erase voltage. The generated erase voltage may be supplied to the memory cell array 620. Accordingly, the current path of the blocks in which corresponding block selection units have become on is formed, and thus the data of the selected four blocks may be erased.

Thereafter, the memory device may perform an erase verification operation on the erased multi-block while performing step 917 and step 919. First, when the memory device selects the erased first block, the sense amplifier 643 may sense the data of the first block. The memory device may sense a pass or fail for the erased first block by analyzing the signal sensed by the sense amplifier 643. Thereafter, the memory device may select the erased second block and repeatedly perform the above operation. That is, the memory device may sequentially select, the last blocks in the first blocks of the erased blocks and perform an erase verification operation on the selected blocks. If erasure is a pass when performing the erase verification operation at step 917 the memory device may turn off the block selection unit of a corresponding block. If erasure is a fail when performing the erase verification operation at step 917, the memory device may maintain the on state of the selection of a corresponding block.

When the erase verification operation is performed on the last erase block, the memory device may recognize the erase verification operation at step 919 and analyze a result of the verification at step 921. At this time, if there is a block that belongs to the erased blocks and that is sensed to have failed, the memory device may recognize such a block at step 923, may return to step 915, and may repeat the erase operation for the block for which the erase operation failed. When performing the erase operation again, the memory device may use an updated erase voltage. For example, the memory device may control the power supply unit 650 so that an erase voltage having a higher level than an erase voltage supplied in a previous erase operation is generated and supplied to the memory cell array 620. At this time, in the memory cell array 620, the block selection unit of an erase-failed block maintains an on state. Accordingly, the memory device may perform an operation for erasing data because the erase voltage is supplied to the erase-failed blocks at the same time at step 915. Furthermore when the erasure of the multi-block is verified to be successful, the memory device may recognize that the erasure of the multi-block is successful at step 923 and terminate the erase operation.

The memory device according to various embodiments of the present invention may erase several blocks within one plane at the same time. When multi-block erase information is received, the memory device may select several blocks located in one plane, that is, an object of erasure, and may perform an erase operation on the selected blocks by applying a high erase voltage to the selected blocks at a time. After performing the erase operation, the memory device may perform an erase verification operation on each of the selected blocks. After performing the erase verification operation, the memory device may determine whether or not to apply a next erase voltage based on a result of the verification, and may apply the next erase voltage to only blocks that require an additional erase voltage. If an erase verification operation for all of the target blocks is a pass (yes at step 923), the memory device may then terminate the erase operation.

The memory device according to various embodiments of the present invention may simultaneously erase several blocks within one plane. Furthermore, the memory device according to various embodiments of the present invention may simultaneously erase a plurality of blocks in parallel in a plurality of planes. For example, in FIG. 7, the memory device may independently generate multi-block erase information for the plane 1 and multi-block erase information for the plane N. In such a case, the memory device may select corresponding blocks, located within the plane 1, as erase blocks based on the multi-block erase information of the plane 1, and may consecutively select corresponding blocks, located within the plane N, as erase blocks based on the multi-block erase information of the plane N. Thereafter, after selecting the last erase block of the plane N, the memory device may supply an erase voltage to the plane 1 and the plane N. Accordingly, the data of the blocks selected in the plane 1 and the blocks selected in the plane N of the memory cell array 620 can be erased at the same time. After simultaneously erasing the selected blocks of the plane 1 and the plane N, the memory device may perform an erase verification operation on each of the planes 1 and N.

The memory device according to various embodiments of the present invention may be a non-volatile memory device, and the non-volatile memory device may be NAND flash memory. Furthermore, the multi-block erase method of the memory device according to various embodiments of the present invention may be applied to both 2-D and 3-D NAND flash memory device.

The memory system and operating method of the memory system in accordance with the aforementioned embodiments of the present invention can reduce an erase time per unit memory capacity by erasing more memory regions of a memory device in the same time. For example, read and write performance of a NAND flash memory device can be improved by reducing the time that is taken for the operation of the NAND flash memory device and that is occupied by an erase operation.

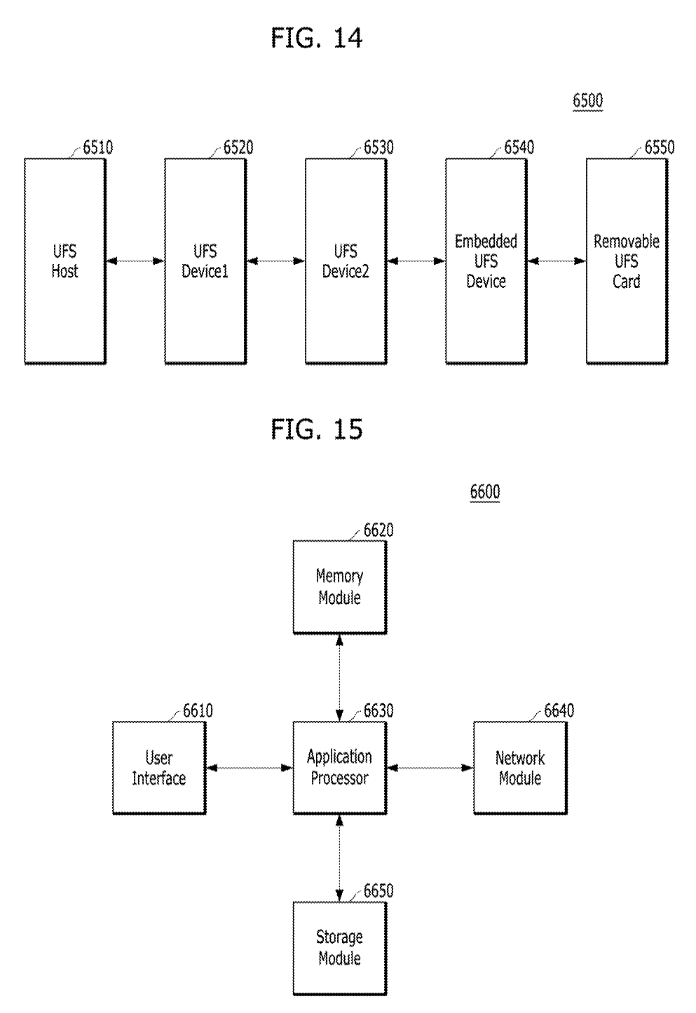

Hereinbelow detailed descriptions will be made with reference to FIGS. 10 to 15, of electronic devices employing a memory system, according to various embodiments of the present invention.

FIG. 10 is a diagram illustrating an example of a data processing system including a memory system according to an embodiment of the present invention. Specifically FIG. 10 illustrates a memory card system 6100 employing a memory system, according to an embodiment of the present invention.

Referring to FIG. 10, the memory card system 6100 is provided, according to an embodiment of the present invention.

The memory card system 6100 may include a memory controller 6120, a memory device 6130, and a connector 6110.

The memory controller 6120 may be operatively connected with the memory device 6130. The memory controller 6120 may access the memory device 6130 for controlling the operations of the memory device 6130. In some embodiments, the memory device 6130 may be implemented with a nonvolatile memory (NVM). For example, the memory controller 6120 may control the read, write, erase and background operations of the memory device 6130. The memory controller 6120 is also configured to provide an interface between the memory device 6130 and a host via the connector 6110. The memory controller 6120 may drive a firmware for controlling the memory device 6130.

The memory controller 6120 may correspond to the controller 130 in the memory system 110 described above with reference to FIG. 1, and the memory device 6130 may correspond to the memory device 150 in the memory system 110 described above with reference to FIG. 1.

Therefore, the memory controller 6120 may include components such as a random access memory (RAM), a processing unit, a host interface, a memory interface and an error correction unit as shown in FIG. 1.

The memory controller 6120 may communicate with an external device, for example, the host 102 described above with reference to FIG. 1, through the connector 6110. For example, as described above with reference to FIG. 1, the memory controller 6120 may be configured to communicate with the external device through at least one of various communication protocols such as a universal serial bus (USB), a multimedia card (MMC), an embedded MMC (eMMC), a peripheral component interconnection (PCI), a PCI-express (PCIe), an Advanced Technology Attachment (ATA), a Serial-ATA, a Parallel-ATA, a small computer system interface (SCSI), an enhanced small disk interface (ESDI), an Integrated Drive Electronics (IDE), a Firewire, universal flash storage (UFS), wireless-fidelity (WI-FI) and a Bluetooth. The memory system and the data processing system may be applied to wired and/or wireless electronic appliances, for example, a mobile electronic appliance.

The memory device 6130 may be a nonvolatile memory (NVM). For example, the memory device 6130 may be implemented with one of various nonvolatile memory devices such as, for example, an erasable and programmable ROM (EPROM), an electrically erasable and programmable ROM (EEPROM), a NAND flash memory, a NOR flash memory, a PRAM, a resistive RAM (ReRAM), a ferroelectric RAM (FRAM) and a spin torque transfer magnetic RAM (STT-MRAM).

The memory controller 6120 and the memory device 6130 may be integrated into a single semiconductor device. For example, the memory controller 6120 and the memory device 6130 may form a solid state drive (SSD) by being integrated into a single semiconductor device. Also, the memory controller 6120 and the memory device 6130 may form a memory card such as a PC card (e.g., Personal Computer Memory Card International Association (PCMCIA)), a compact flash card (CF), a smart media card (e.g., SM and SMC), a memory stick, a multimedia card (e.g., MMC, RS-MMC, MMCmicro and eMMC), an SD card (e.g., SD, miniSD, microSD and SDHC) and a universal flash storage (UFS).

FIG. 11 is a diagram illustrating another example of a data processing system 6200 including a memory system, according to an embodiment of the present invention.

Referring to FIG. 11, the data processing system 6200 may include a memory device 6230 which is implemented by at least one nonvolatile memory NVM and a memory controller 6220 which controls the memory device 6230. The data processing system 6200 may be a storage medium such as a memory card (e.g., a CF, a SD or a microSD), as described above with reference to FIG. 1. The memory device 6230 may correspond to the memory device 150 in the memory system 110 described above with reference to FIG. 1. The memory controller 6220 may correspond to the controller 130 in the memory system 110 described above with reference to FIG. 1.

The memory controller 6220 may control the operations for the memory device 6230 including read, write and erase operations in response to commands received from a host 6210. The memory controller 6220 may include at least one of a central processing unit (CPU) 6221, a random access memory (RAM) as a buffer memory 6222, an error correction code (ECC) circuit 6223, a host interface 6224, and an. NVM interface as a memory interface 6225, all electrically coupled via an internal bus.

The CPU 6221 may control the operations for the memory device 6230, for example, read, write, file system management, bad page management, and so forth. The RAM 6222 may operate according to control of the CPU 6221, and may be used as a work memory, a buffer memory, a cache memory, or the like. In the case where the RAM 6222 is used as a work memory, data processed by the CPU 6221 is temporarily stored in the RAM 6222. In the case where the RAM 6222 is used as a buffer memory, the RAM 6222 may be used to buffer data to be transmitted from the host: 6210 to the memory device 6230 or from the memory device 6230 to the host 6210. In the case where the RAM 6222 is used as a cache memory, the RAM 6222 may be used to enable the memory device 6230 of a low speed to operate at a high speed.

The ECC circuit 6223 may correspond to the ECC unit 138 of the controller 130 described above with reference to FIG. 1. As described above with reference to FIG. 1, the ECC circuit 6223 may generate an error correction code (ECC) for correcting a fail bit or an error bit in the data received from the memory device 6230. Also, the ECC circuit 6223 may perform error correction encoding for data to be provided to the memory device 6230, and may generate data added with parity bits. The parity bits may be stored in the memory device 6230. The ECC circuit 6223 may perform error correction decoding for data outputted from the memory device 6230. At this time, the ECC circuit 6223 may correct errors by using the parity bits. For example, as described above with reference to FIG. 1, the ECC circuit 6223 may correct errors by using one of various coded modulations such as a low density parity check (LDPC) code, a Bose-Chaudhuri-Hocquenghem (BCH) code, a turbo code, a Reed-Solomon (RS) code, a convolution code, a recursive systematic code (RSC), a trellis-coded modulation (TCM) and a Block coded modulation (BCM).

The memory controller 6220 may transmit and receive data to and from the host 6210 through the host interface 6224, and transmit and receive data to and from the memory device 6230 through the NVM interface 6225. The host interface 6224 may be connected with the host 6210 through at least one of various interface protocols such as a parallel advanced technology attachment (PATA) bus, a serial advanced technology attachment (SATA) bus, a small computer system interface (SCSI), a universal serial bus (USB), a peripheral component interconnection express (PCIe) or a NAND interface. Further, as a wireless communication function or a mobile communication protocol such as wireless fidelity (WI-FI) or long term evolution (LTE) is implemented the memory controller 6220 may transmit and receive data by being connected with an external device, for example, the host 6210 or another external device other than the host 6210. Specifically, as the memory controller 6220 is configured to communicate with an external device through at least one among various communication protocols, the memory system and the data processing system according to the embodiment may be applied to wired and/or wireless electronic appliances, in particular, a mobile electronic appliance.

FIG. 12 is a diagram illustrating another example of a data processing system including a memory system according to an embodiment of the present invention. For example, in FIG. 12, a solid state drive (SSD) 6300 employing a memory system is shown.

Referring to FIG. 12, the SSD 6300 may include a memory device 6340 which includes a plurality of nonvolatile memories NVM, and a controller 6320. The controller 6320 may correspond to the controller 130 in the memory system 110 described above with reference to FIG. 1. The memory device 6340 may correspond to the memory device 150 in the memory system 110 described above with reference to FIG. 1.

The controller 6320 may be connected with the memory device 6340 through a plurality of channels CH1, CH2, CH3, and CHi. The controller 6320 may include at least one processor 6321 a buffer memory 6325, an error correction code (ECC) circuit 6322, a host interface 6324, and a nonvolatile memory (NVM) interface as a memory interface 6326 coupled via an internal bus.

The buffer memory 6325 may temporarily store data received from a host 6310 or data received from a plurality of nonvolatile memories NVM included in the memory device 6340, or temporarily store metadata of the plurality of nonvolatile memories NVM. For example, the metadata may include map data including mapping tables. The buffer memory 6325 may be implemented by a volatile memory such as, but not limited to, a dynamic random access memory (DRAM), a synchronous dynamic random access memory (SDRAM), a double data rate (DDR) SDRAM, a low power double data rate (LPDDR) SDRAM and a graphic random access memory (GRAM) or a nonvolatile memory such as, but not limited to, a ferroelectric random access memory (FRAM), a resistive random access memory (ReRAM), a spin-transfer torque magnetic random access memory (STT-MRAM) and a phase change random access memory (PRAM) While it is illustrated in FIG. 10, as an example, that the buffer memory 6325 is disposed inside the controller 6320, it is noted that the buffer memory 6325 may be disposed outside the controller 6320.

The ECC circuit 6322 may calculate error correction code values of data to be programmed in the memory device 6340 in a program operation, perform an error correction operation for data read from the memory device 6340, based on the error correction code values, in a read operation, and perform an error correction operation for data recovered from the memory device 6340 in a recovery operation for failed data.

The host interface 6324 may provide an interface function with respect to an external device, for example, the host 6310. The nonvolatile memory interface 6326 may provide an interface function with respect to the memory device 6340 which is connected through the plurality of channels CH1, CH2, CH3, . . . and CHi.

As a plurality of SSDs 6300 to each of which the memory system 110 described above with reference to FIG. 1 is applied are used, a data processing system such as a redundant array of independent disks (RAID) system may be implemented. In the RAID system, the plurality of SSDs 6300 and a RAID controller for controlling the plurality of SSDs 6300 may be included. In the case of performing a program operation by receiving a write command from the host 6310, the RAID controller may select at least one memory system, (for example, at least one SSD 6300) in response to the RAID level information of the write command received from the host 6310, among a plurality of RAID levels, (for example, the plurality of SSDs 6300) and may output data corresponding to the write command, to the selected SSD 6300. In the case of performing a read operation by receiving a read command from the host 6310, the RAID controller may select at least one memory system, (for example, at least one SSD 6300) in response to the RAID level information of the write command received from the host 6310, among the plurality of RAID levels, (for example, the plurality of SSDs 6300), and may provide data outputted from the selected SSD 6300, to the host 6310.

FIG. 13 is a diagram illustrating another example of a data processing system including a memory system, according to an embodiment of the present invention. For example, in FIG. 13, an embedded multimedia card (eMMC) 6400 employing a memory system is shown.

Referring to FIG. 13, the eMMC 6400 may include a memory device 6440 which is implemented by at least one NAND flash memory, and a controller 6430. The controller 6430 may correspond to the controller 130 in the memory system 110 described above with reference to FIG. 1. The memory device 6440 may correspond to the memory device 150 in the memory system 110 described above with reference to FIG. 1.

The controller 6430 may be connected with the memory device 6440 through a plurality of channels. The controller 6430 may include a core 6432, a host interface 6431, and a memory interface such as a NAND interface 6433.

The core 6432 may control the operations of the eMMC 6400. The host interface 6431 may provide an interface function between the controller 6430 and a host 6410. The NAND interface 6433 may provide an interface function between the memory device 6440 and the controller 6430. For example, the host interface 6431 may be a parallel interface, for example, an MMC interface, as described above with reference to FIG. 1, or may be a serial interface, for example, an ultra-high speed class 1 (UHS-I)/UHS class 2 (UHS-II) and a universal flash storage (UFS) interface,

FIG. 14 is a diagram illustrating another example of a data processing system including a memory system, according to an embodiment: of the present invention. For example, FIG. 14 illustrates a universal flash storage (UFS) system 6500 employing a memory system according to an embodiment of the invention.

Referring to FIG. 14, the UFS system 6500 may include a UFS host 6510, a plurality of UFS devices 6520 and 6530, an embedded UFS device 6540, and a removable UFS card 6550. The UFS host 6510 may be an application processor of wired and/or wireless electronic appliances, in particular, a mobile electronic appliance

The UFS host 6510, the UFS devices 6520 and 6530, the embedded UFS device 6540 and the removable UFS card 6550 may respectively communicate with external devices such as wired and/or wireless electronic appliances, in particular, a mobile electronic appliance, for example, through a UFS protocol. The UFS devices 6520 and 6530, the embedded UFS device 6540 and the removable UFS card 6550 may be implemented as the memory system 110 described above with reference to FIG. 1, in particular, as the memory card system 6100 described above with reference to FIG. 10. The embedded UFS device 6540 and the removable UFS card 6550 may also communicate through another protocol other than the UFS protocol. For example, the embedded UFS device 6540 and the removable UFS card 6550 may communicate through various card protocols, for example, but not limited to, USB flash drives (UFDs), multimedia card (MMC), secure digital (SD), mini SD and Micro SD.

FIG. 15 is a diagram illustrating another example of a data processing system including a memory system according to an embodiment of the present invention. For example, in FIG. 15, a user system 6600 employing the memory system is shown.

Referring to FIG. 15, the user system 6600 may include a user interface 6610, a memory module 6620, an application processor 6630, a network module 6640 and a storage module 6650.

The application processor 6630 may drive components included in the user system 6600 and an operating system (OS). For example, the application processor 6630 may include controllers for controlling the components included in the user system 6600, interfaces, graphics engines, and so on. The application processor 6630 may be provided by a system-on-chip (SoC).

The memory module 6620 may operate as a main memory, a working memory, a buffer memory or a cache memory of the user system 6600. The memory module 6620 may include a volatile random access memory such as a dynamic random access memory (DRAM), a synchronous dynamic random access memory (SDRAM), a double data rate (DDR) SDRAM, a DDR2 SDRAM, a DDR3 SDRAM, a low power double data rate (LPDDR) SDRAM, an LPDDR2 SDRAM and an LPDDR3 SDRAM or a nonvolatile random access memory such as a phase change random access memory (PRAM), a resistive random access memory (ReRAM), a magnetic random access memory (MRAM) and a ferroelectric random access memory (FRAM). For example, the application processor 6630 and the memory module 6620 may be mounted by being packaged on the basis of a package-on-package (POP).

The network module 6640 may communicate with external devices. For example, the network module 6640 may support not only wired communications but also various wireless communications such as code division multiple access (CDMA), global system for mobile communication (GSM), wideband CDMA (WCDMA), CDMA-2000, time division multiple access (TDMA), long term evolution (LTE), worldwide interoperability for microwave access) (WiMAX), wireless local area network (WLAN), ultra-wideband (UWB), Bluetooth, wireless display (WI-DI), and so on, and may thereby communicate with wired and/or wireless electronic appliances, in particular, a mobile electronic appliance. Accordingly, the memory system and the data processing system may be applied to wired and/or wireless electronic appliances. The network module 6640 may be included in the application processor 6630.

The storage module 6650 may store data such as data received from the application processor 6630, and transmit data stored therein, to the application processor 6630. The storage module 6650 may be implemented by a nonvolatile semiconductor memory device such as a phase-change RAM (PRAM), a magnetic RAM (MRAM), a resistive RAM (ReRAM), a NAND flash memory, a NOR flash memory and a 3-dimensional NAND flash memory. The storage module 6650 may be provided as a removable storage medium such as a memory card of the user system 6600 and an external drive. For example, the storage module 6650 may correspond to the memory system 110 described above with reference to FIG. 1, and may be implemented as the SSD, eMMC and UFS described above with reference to FIGS. 12 to 14.

The user interface 6610 may include interfaces for inputting data or commands to the application processor 6630 or for outputting data to an external device. For example, the user interface 6610 may include user input interfaces such as a keyboard, a keypad, a button, a touch panel, a touch screen, a touch pad, a touch ball, a camera, a microphone, a gyroscope sensor, a vibration sensor and a piezoelectric element, and user output interfaces such as a liquid crystal display (LCD), an organic light emitting diode (OLED) display device, an active matrix OLED (AMOLED) display device, a light emitting diode (LED), a speaker and a motor.

In the case where the memory system 110 described above with reference to FIG. 1 is applied to the mobile electronic appliance of the user system 6600 according to an embodiment, the application processor 6630 may control the operations of the mobile electronic appliance, and the network module 6640 as a communication module controls wired and/or wireless communication with an external device, as described above. The user interface 6610 as the display/touch module of the mobile electronic appliance displays data processed by the application processor 6630 or supports input of data from a touch panel.

Although various embodiments have been described for illustrative purposes, it will be apparent to those skilled in the art that various other changes and modifications may be made without departing from the spirit and scope of the invention as, defined in the following claims.

1. A memory device, comprising:
a memory cell array including a plurality of blocks;
a power supply unit configured to generate at least one erase voltage and supply the at least one erase voltage to the memory cell array;
a control logic configured to receive multi-block erase information for multiple blocks to be simultaneously erased within an identical plane, transmit the multi-block erase information and outputting an erase control signal to the power supply unit; and
a row decoder configured to receiving the multi-block erase information and select the multiple blocks of the memory cell array based on the multi-block erase information,
wherein the multi-block erase information includes a plurality of block erase information,
wherein each of the plurality of block erase information includes a first command for indicating a start of a block to be erased, block address information regarding an address for a block to be erased and a second command for indicating an end of a block to be erased and whether the corresponding block to be erased is a last block among the multiple blocks.

2. The memory device of claim 1, wherein the control logic is configured to determine whether an erase-failed block of the multiple blocks is present, and controlling the power supply unit so that an updated erase voltage is supplied again if the erase-failed block is present.

3. The memory device of claim 2, wherein the updated erase voltage is higher than a previous erase voltage.

4. The memory device of claim 1, wherein
last block erase information of the plurality of block erase information comprises an erase command as the first command, last block address information regarding an address for the last block to be erased and an erase confirm command as the second command indicating whether the corresponding block to be erased is the last block among the multiple blocks.

5. The memory device of claim 4, wherein the control logic is configured to:
outputting the corresponding block address information to the row decoder when the second command is recognized in one of the plurality of block erase information included in the multi-block erase information

6. The memory device of claim 5, wherein multiple block address information included in the plurality of block erase information comprise consecutive block address information.

7. The memory device of claim 5, wherein multiple block address information included in the plurality of block erase information comprise inconsecutive block address information.

8. The memory device of claim 2, further comprising a verification circuit configured to verify an erase state of the multiple blocks in the memory cell array.

9. The memory device of claim 8, wherein the control logic is configured to:
perform control so that a selection of an erase-pass block is released and a selection of an erase-failed block is maintained based on the verification result of the verification circuit.

10. The memory device of claim 9, wherein the control logic is further configured to:
checking whether the erase-failed block is present or not when the verification of the multiple blocks is completed, and
controlling the power supply unit so that the updated erase voltage is supplied if, as a result of the check, the erase-failed block is present.

11. An operating method of a memory device, comprising:
receiving multi-block erase information for multiple blocks to be simultaneously erased within an identical plane of a memory cell array including a plurality of blocks;
decoding block address information included in the multi-block erase information for the identical plane of the memory cell array;
supplying an erase voltage to the multiple blocks of the memory cell array based on the multi-block erase information; and
simultaneously erasing the multiple blocks selected in the identical plane of the memory cell array based on the multi-block erase information using the erase voltage,
wherein the multi-block erase information includes a plurality of block erase information,
wherein each of the plurality of block erase information includes a first command for indicating a start of a block to be erased, block address information regarding an address for a block to be erased and a second command for indicating an end of a block to be erased and whether the corresponding block to be erased is a last block among the multiple blocks.

12. The method of claim 11, further comprising:
verifying an erase state of the multiple blocks-in the memory cell array; and
performing control so that a selection of the multiple blocks is released or maintained, based on the verification result.

13. The method of claim 12, further comprising: erasing data of the erase-failed block by supplying an updated erase voltage to the memory cell array again if the erase-failed block is present.

14. The method of claim 1, wherein
last block erase information of the plurality of block erase information comprises an erase command as the first command, last block address information regarding an address for a the last block to be erased and an erase confirm command as the second command indicating whether the corresponding block to be erased is the last block among the multiple blocks.

15. The method of claim 14, wherein the decoding block addresses included in the multi-block erase information for the identical plane comprises:
decoding the corresponding block address information and turning on a corresponding block of the memory cell array when the second command is recognized in one of the plurality of block erase information included in the multi-block erase information.

16. The method of claim 15, wherein multiple block address information included in the plurality of block erase information comprise consecutive block address information.

17. The method of claim 15, wherein multiple block address information included in the plurality of block erase information comprise inconsecutive block address information.

18. The method of claim 12, further comprising: verifying an erase state of the multiple blocks in the memory cell array.

19. The method of claim 18, wherein the verifying of the erase state of the multiple blocks comprises:
releasing a selection of an erase-pass block of the memory cell array based on a result of the verification;
maintaining a selection of an erase-failed block of the memory cell array based on a result of the verification; and
supplying an updated erase voltage to the erase-failed blocks when the verification of the multiple blocks is completed.

20. The method of claim 19, wherein the updated erase voltage is higher than a previous erase voltage.
